(19) United States
(12) Patent Application Publication
(10) Pub. No.: US 2021/0120688 A1
(43) Pub. Date: Apr. 22, 2021

(54) FLEXIBLE DISPLAY SCREEN SUPPORT MECHANISM AND FLEXIBLE DISPLAY DEVICE

(71) Applicant: SHENZHEN ROYOLE TECHNOLOGIES CO., LTD., Shenzhen (CN)

(72) Inventor: Zhengxi WANG, Shenzhen (CN)

(21) Appl. No.: 17/135,100

(22) Filed: Dec. 28, 2020

Related U.S. Application Data
(63) Continuation of application No. PCT/CN2018/094323, filed on Jul. 3, 2018.

(51) Int. Cl. H05K 5/02; H05K 5/00; F16C 11/04; G06F 1/16

(52) U.S. Cl. CPC H05K 5/0226; H05K 5/0017; G06F 1/1681; G06F 1/1652; F16C 11/04

(57) ABSTRACT

The flexible display screen support mechanism for supporting a flexible display screen including a bending area includes a support member operable to arrange on a back side of the flexible display screen, a hinge corresponds to the bendable area and arranged on one side of the support member away from the flexible display screen, and a position limiting apparatus passes through the hinge and fixed on the support member. The position limiting apparatus is operable to generate an action force to pull the support member and the hinge toward each other. The position limiting apparatus passes through the hinge and is fixed on the support member, thereby ensuring the connection between the support member and the hinge when the flexible display device is in different states, preventing detachment of the bendable area of the flexible display screen from the hinge, and thereby avoiding damages caused to the flexible display screen.

This application is a continuation of International Application No. PCT/CN2018/094323, filed on Jul. 3, 2018. The disclosures of the aforementioned applications are hereby incorporated by reference in their entireties.

### TECHNICAL FIELD

The present application relates to a technical field of display, more particularly relates to a flexible display screen support mechanism and a flexible display device.

### BACKGROUND

With the development of display technology, consumers have more and more diversified and personalized demands for display methods and display effects of display devices. Compared with traditional display devices, flexible display screens have the advantages of being bendable and stretchable, and are widely favored by consumers.

The existing flexible display devices have flexible display screens fitted and fixed on support members, and the flexible display screens are bent by hinges. However, when the flexible display devices are squeezed by an external force, the support members are easily separated from chains of the hinges and arches in bending areas, thereby causing damage and failure of the flexible display screens.

### SUMMARY

The present disclosure provides a flexible display screen support mechanism and a flexible display device, which are not easy to be damaged.

In order to achieve the above objectives, embodiments of the present disclosure provide the following technical solutions.

In a first aspect, the present disclosure provides a flexible display screen support mechanism operable to support a flexible display screen. The flexible display screen includes a bendable area. The flexible display screen support mechanism includes:

a support member arranged on a back side of the flexible display screen;

a hinge corresponding to the bendable area of the flexible display screen and arranged on one side of the support member away from the flexible display screen; and

a position limiting apparatus passing through the hinge and fixed on the support member, therein the position limiting apparatus is operable to generate an action force to pull the support member and the hinge toward each other.

In a second aspect, the present disclosure provides a flexible display device comprising the above flexible display screen support mechanism and a flexible display screen, the flexible display screen support mechanism is arranged on a back side of the flexible display screen.

Compared with the related art, the flexible display screen support mechanism and the flexible display device of the embodiments of the present disclosure provide the position limiting apparatus passing through the hinge and fixed on the support member, thereby ensuring the connection between the support member and the hinge when the flexible display device is in different states, preventing detachment of the bendable area of the flexible display screen from the hinge, and thereby avoiding damages caused to the flexible display screen.

### BRIEF DESCRIPTION OF THE DRAWINGS

In order to more clearly illustrate the technical solution of the present disclosure or the related art, the accompanying drawings required for describing the embodiments or the related art will be briefly described below. Apparently, the accompanying drawings in the following description are merely the embodiments of the present disclosure, and other drawings may be obtained by those skilled in the art according to these accompanying drawings without paying any creative labor.

FIG. 1 is an exploded schematic view of a three-dimensional structure of a flexible display device provided by an embodiment of the present disclosure.

FIG. 2 is an exploded schematic view of a flexible display screen support mechanism of the flexible display device of FIG. 1.

FIG. 3 is an inverted view of FIG. 2.

FIG. 4 is an enlarged view of a hinge, a position limiting fixing member, and a mounting member of the flexible display screen support mechanism of FIG. 2.

FIG. 5 is an inverted view of FIG. 4.

FIG. 6 is a cross-sectional view of the flexible display device of FIG. 1, taken along the line of VI-VI.

FIG. 7 is a partial enlarged view of FIG. 6.

FIG. 8 is a schematic structural view of the flexible display device of FIG. 1, which is in a bent state.

FIG. 9 is a cross-sectional view of the flexible display device of FIG. 8, taken along the line of IX-IX.

### DETAILED DESCRIPTION

The technical solutions in the embodiments of the present disclosure are clearly and completely described below with reference to the accompanying drawings in the embodiments of the present disclosure.

It will be apprehended that, the terms used herein is for the purpose of describing particular embodiments only, and is not intended to limit the disclosure. As used herein, the singular forms “a” and “the” are intended to include the plural forms as well, unless the context clearly indicates otherwise. Furthermore, the terms “include” and/or “comprise” when used in this specification indicate the presence of stated features, integers, steps, elements, and/or components, but do not preclude the presence or addition of one or more other features, integers, presence, or addition of steps, elements, components, and/or groups thereof. Described later in the specification is a preferred embodiment for carrying out the present disclosure. However, the description is for the purpose illustrating the general principles of the present disclosure, and the description is not intended to limit the scope of the present disclosure. The scope of the present disclosure should be defined by the appended claims.

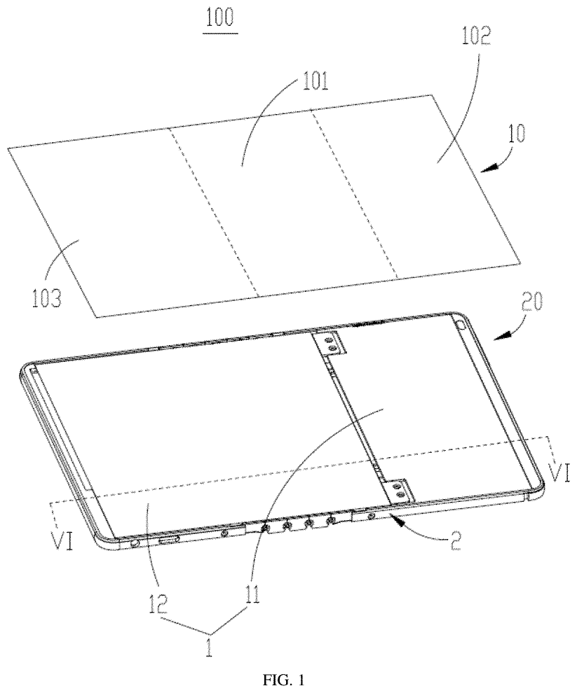

As illustrated in FIG. 1, embodiments of present disclosure provide a flexible display device 100. The flexible display device 100 includes a flexible display screen 10 and a flexible display screen support mechanism 20 arranged on a back side of the flexible display screen 10. The flexible display screen support mechanism 20 is operable to support and protect the flexible display screen 10. The flexible display screen 10 includes a bendable area 101. In the embodiment, the bendable area 101 is located in a middle portion of the flexible display screen 10. Therefore, two ends of the flexible display screen 10 are a first non-bending area 102 and a second non-bending area 103, respectively.

The bendable area 101 of the flexible display screen 10 can be deformed along with the flexible display screen support mechanism 20, such that the flexible display device 100 can have different forms to meet the application requirements of different occasions. The forms of the flexible display device 100 include an unfolded state and a bent state. When the bendable area 101 of the flexible display screen 10 is not bent, the flexible display device 100 is in the unfolded state. When the bendable area 101 of the flexible display screen 10 is bent, the flexible display device 100 is in the bent state, such that it is convenient for the user to carry or operate with one hand.

It will be apprehended that, in the embodiment, the flexible display device 100 is, for example, but not limited to a mobile phone, a tablet computer, a display, a liquid crystal panel, an OLED panel, a TV, a smart watch, a VR head-mounted display, a car display, or any product or component with display function. The flexible display screen 10 is, for example, a flexible touch screen or a flexible display screen. The flexible display screen is, for example, but not limited to a liquid crystal display (LCD) panel, a quantum dot light emitting diodes (QLED) panel, an E-paper Display (EPD), a touch screen, a flexible solar panel, a radio frequency identification (RFID) and other products or components with display functions.

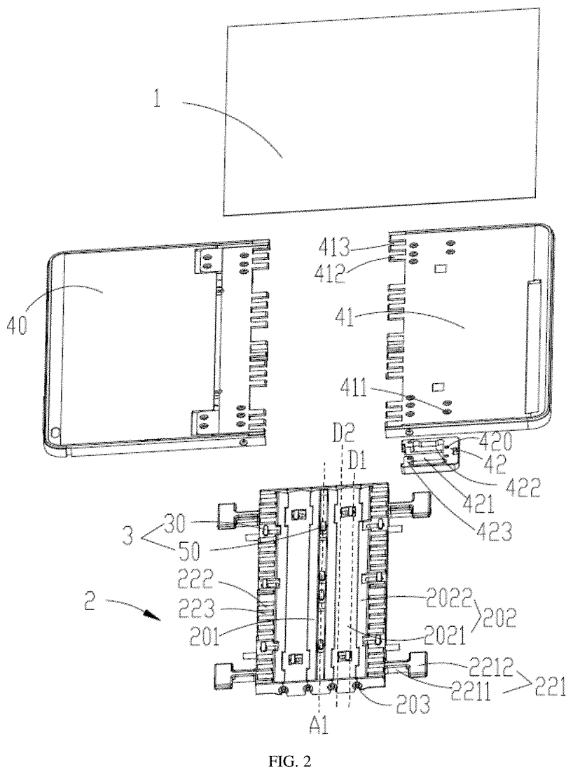

As illustrated in FIG. 1 and FIG. 2, in the embodiment, the flexible display screen support mechanism 20 includes a support member 1, a hinge 2, and a position limiting apparatus 3. Specifically, the support member 1 is arranged on the back side of the flexible display screen 10. The hinge 2 corresponds to the bendable area 101 of the flexible display screen 10 and is arranged on one side of the support member 1 away from the flexible display screen 10. That is, the support member 1 is arranged between the flexible display screen 10 and the hinge 2. The position limiting apparatus 3 passes through the hinge 2 and is fixed on the support member 1. The position limiting apparatus 3 is operable to generate an action force to pull the support member 1 and the hinge 2 toward each other.

In the embodiment, the position limiting apparatus 3 slidably passes through the hinge 2 to be fixed on the support member 1. The support member 1 includes a support surface for supporting the flexible display screen 10. The position limiting apparatus 3 passes through the hinge 2 in a direction perpendicular to the support surface of the support member 1, and the position limiting apparatus 3 is slidable along a direction parallel to the support surface of the support member 1. The support surface of the support member 1 is a side surface of the support member 1 faced away from the hinge 2. When the flexible display screen support mechanism 20 is bent, the position limiting apparatus 3 slides relative to the hinge 2 toward a bending central axis A1 of the flexible display screen support mechanism 20. When two opposite sides of the hinge 2 are stressed, the position limiting apparatus 3 pulls the support member 1 to deform to allow the hinge 2 and the support member 1 to be arched together.

In the embodiment, the support member 1 includes a first support member 11 and a second support member 12. The first support member 11 is arranged on a back side of the first non-bending area 102 of the flexible display screen 10, and the second support member 12 is arranged on a back side of the bendable area 101 of the flexible display screen 10 and a back side of the second non-bending area 103 of the flexible display screen 10. In another embodiment, the support member 1 is only arranged on a back side of the bendable area 101 of the flexible display screen 10. That is, the flexible display screen support mechanism 20 only includes one support member 1, which is arranged on a back side of the bendable area 101 of the flexible display screen 10.

The support member 1 can be fixed to the back side of the flexible display screen 10 by a specific manner, including but not limited to gluing or welding. Of course, the support member 1 may not be fixed to the flexible display screen 10, but the support member 1 may be slidably fitted to the flexible display screen 10, such that the support member 1 and the flexible display screen 10 can slide relative to each other. The support member 1 is made of elastic material, such as rubber material. In another embodiment, the support member 1 is made of material with higher hardness and better elasticity, such as steel sheet, liquid metal. Optionally, a hardness of support member 1 is greater than a hardness of the flexible display screen 10, thus improving the hardness and strength of the entire flexible display device 100, thereby improving the user's operating experience.

In the embodiment, the position limiting apparatus 3 includes a position limiting fixing member 30. The position limiting fixing member 30 is fixedly arranged on the supporting member 1 and is slidably coupled to the hinge 2. Specifically, the position limiting fixing member 30 is fixed on the second support member 12. When the flexible display device 100 changes from the unfolded state to the bent state, the position limiting fixing member 30 slides from a first position D1 of the hinge 2 to a second position D2 of the hinge 2. When the flexible display device 100 changes from the bent state to the unfolded state, the position limiting fixing member 30 slides from the second position D2 of the hinge 2 to the first position D1 of the hinge 2. Such that the connection between the support member 1 and the hinge 2 when the flexible display device 100 is in different states can be ensured by the sliding of the position limiting fixing member 30 between the first position D1 and the second position D2 on the hinge 2, and damages caused to the flexible display screen can be avoided.

As illustrated in FIG. 2, the hinge 2 includes a fixing chain 201 and a rotating chain 202 arranged on one side of the fixing chain 201. In the embodiment, each side of the fixing chain 201 is provided with the rotating chain 202. That is, the hinge 2 includes at least two rotating chains 202. The fixing chain 201 is fixedly arranged on the support member 1, and the at least two rotating chains 202 are rotatably coupled to the fixing chain 201. Optionally, the at least two rotating chains 202 arranged on two opposite sides of the fixing chain 201 are symmetrically arranged relative to the fixing chain 201.

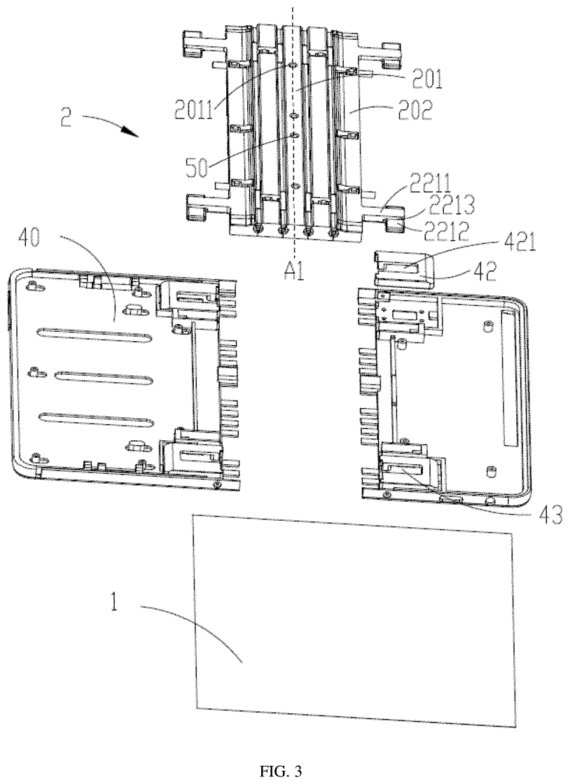

The hinge 2 further includes a plurality of rotating shafts 203. Each of the at least two rotating chains 202 is rotatably coupled to the fixing chain 201 by the rotating shaft 203. The position limiting apparatus 3 further includes a mounting member 50. The fixing chain 201 is fixed on the support member 1 by the mounting member 50. The fixing chain 201 defines a plurality of through holes 2011 for the mounting member 50 to pass through in a length direction thereof (see FIG. 3). In the embodiment, the position limiting apparatus 3 includes a plurality of mounting members 50. The number of the plurality of through holes 2011 corresponds to the number of the plurality of mounting members 50. Optionally, in one embodiment, the through hole 2011 is a threaded hole, and the mounting member 50 is a screw, such that the mounting member 50 is locked in the through hole 2011 of the fixing chain 201. The fixing chain 201 is fixed to the support member 1 by a screw. In another embodiment, a maximum diameter of the mounting member 50 is greater than a diameter of the through hole 2011, such that the mounting member 50 can be locked in the through hole 2011.

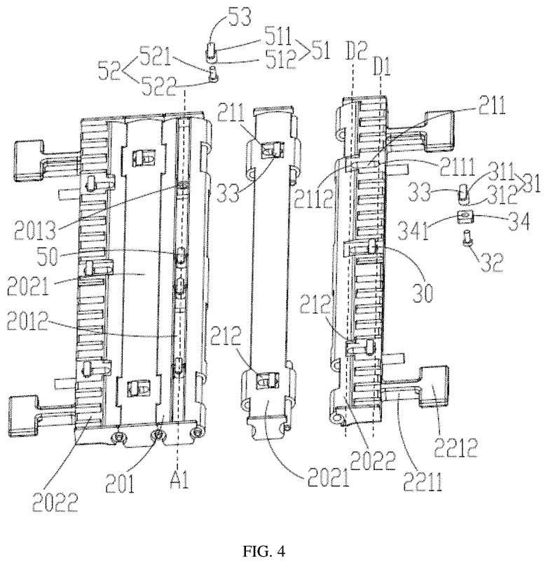

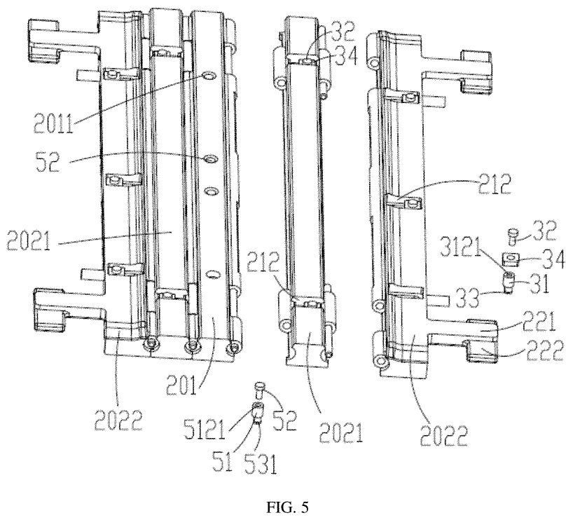

As illustrated in FIG. 3 and FIG. 4, in another embodiment, the fixing chain 201 can be fixed to the support member 1 by other means, such as welding or glue. Specifically, the mounting member 50 includes a cylindrical main body 51. The main body 51 includes a connecting end 511 and a free end 512 opposite to the connecting end 511. The connecting end 511 of the main body 51 is fixed to the support member 1. The free end 512 of the main body 51 is fixedly coupled to the fixing chain 201. In another embodiment, the mounting member 50 further includes a locking member 52. The locking member 52 is arranged on the free end 512 of the main body 51 and is locked in the through hole 2011. Specifically, the free end 512 of the main body 51 defines a locking hole 5121 (see FIG. 5) matched with the locking member 52 in an axial direction of the main body 51, and the locking hole 5121 is aligned with the through hole 2011 of the fixing chain 201.

In the embodiment, the main body 51 is a threaded sleeve, and the locking member 52 is a screw in threaded engagement with the threaded sleeve. In other embodiments, the main body 51 is a stud, and the locking member 52 is a nut in threaded engagement with the stud. The mounting member 50 further includes a welding gasket 53. The connecting end 511 of the main body 51 is fixed to the support member 1 by the welding gasket 53. Specifically, the main body 51 is welded to the welding gasket 53, and then the welding gasket 53 is fixed to the support member 1. The welding gasket 53 can be fixed to the support member 1 by welding. It will be apprehended that, in other embodiments, the welding gasket 53 may also be fixed to the support member 1 by adhesive.

Furthermore, the locking member 52 includes a connecting portion 521 and a position limiting portion 522. The connecting portion 521 of the locking member 52 passes through the through hole 2011 of the fixing chain 201 and then is locked in the locking hole 5121 of the main body 51. A diameter of the position limiting portion 522 of the locking member 52 is larger than a diameter of the through hole 2011 of the fixing chain 201, thus realizing the locking member 52 to be locked in the through hole 2011 of the fixing chain 201, and thereby realizing the support member 1 to be fixedly coupled to the fixing chain 202 of the hinge 2.

Optionally, the fixing chain 201 defines a receiving groove 2012 for receiving the main body 51 of the mounting member 50 in a length direction of the fixing chain 201. A bottom of the receiving groove 2012 defines a positioning groove 2013 matched with the free end 512 of the main body 51, thus facilitating the assembly of the mounting member 50.

In the embodiment, since the fixing chain 201 is fixedly arranged on the support member 1, when the support member 1 or the flexible display device 100 is bent, the fixing chain 201 is defined as a central axis of the flexible display screen support mechanism 20 or a central axis of the flexible display device 100. That is, the at least two rotating chains 202 located on two sides of the fixing chain 201 are rotated around the fixing chain 201, respectively. Such that the flexible display screen support mechanism 20 or the flexible display screen 10 can be bent or unfolded.

The rotating chain 202 defines a sliding groove 211 for the position limiting fixing member 30 sliding. The sliding groove 211 extends on the rotating chain 202 along a width direction of the rotating chain 202. When the support member 1 or the flexible display device 100 is bent, the position limiting fixing member 30 slides from a first position D1 of the sliding groove 211 to a second position D2 of the sliding groove 211. The sliding groove 211 includes a first end 2111 and a second end 2112 opposite to the first end 2111. The first end 2111 is an end of the sliding groove 211 far away from the fixing chain 201 (that is an outer end), and the second end 2112 is an end of the sliding groove 211 close to the fixing chain 201 (that is an inner end). The first position D1 is located at the first end 2111 of the sliding groove 211, and the second position D2 is located at the second end 2112 of the sliding groove 211. When the flexible display screen support mechanism 20 and the flexible display device 100 are in the unfolded state, the position limiting fixing member 30 is located at the first position D1 of the sliding groove 211. When the flexible display screen support mechanism 20 and the flexible display device 100 are in the bent state, the position limiting fixing member 30 is located at the second position D2 of the sliding groove 211.

It will be apprehended that, when the flexible display screen support mechanism 20 and the flexible display device 100 are bent, the position limiting fixing member 30 will gradually slide from the first position D1 of the sliding groove 211 to the second position D2 of the sliding groove 211 as a bending angle of the flexible display screen support mechanism 20 or a bending angle of the flexible display device 100 increases. When the bending angle of the flexible display screen support mechanism 20 or the flexible display device 100 increases to a maximum angle, the position limiting fixing member 30 slides to the second position D2 (that is the inner end) of the sliding groove 211. On the contrary, when the flexible display screen support mechanism 20 and the flexible display device 100 are unfolded, the position limiting fixing member 30 will slide from the second position D2 of the sliding groove 211 to the first position D1 (that is the outer end) of sliding groove 211.

In the embodiment, the hinge 2 includes one bending center axis A1 (that is a central axis). The hinge 2 can be bent or unfolded relative to the bending central axis A1 to drive the bending or unfolding of the entire flexible display device 100. In other embodiments, the hinge 2 may include a plurality of bending central axes, and the hinge 2 can be bent or unfolded relative to different bending central axes.

Optionally, the fixing chain 201 is arranged at a position corresponding to the bending central axis A1 of the hinge 2. Lengths of the sliding grooves 211 defined on the same rotating chain 202 are the same, and lengths of the sliding grooves 211 defined on different rotating chains 202 gradually increase from the bending central axis A1 toward a direction away from the bending central axis A1. That is, the length of the sliding grooves 211 is proportional to a distance between corresponding rotating chain 202 and the bending central axis A1. Such that when the position limiting fixing member 30 slides in the sliding groove 211, the support member 1 may be tightened by the position limiting fixing member 30, and the support member 1 may have a smooth and continuous curved surface when the support member 1 is bent, thus preventing the support member 1 from separating from the rotating chain 202 and arching in the bendable area 101, and thereby avoiding damages caused to the flexible display screen. Specifically, if the rotating chain 202 is closer to the bending axis A1, the length of the corresponding sliding groove 211 defined on the rotating chain 202 is smaller. If the rotating chain 202 is farther from the bending axis A1, the length of the corresponding sliding groove 211 defined on the rotating chain 202 is greater.

In an embodiment, the sliding groove 211 is a through groove defined in the rotating chain 202.

Furthermore, the rotating chain 202 defines two opposite receiving grooves 212 in air communication with the sliding groove 211 along a periphery of the sliding groove 211. Specifically, one of the receiving grooves 212 is arranged on one side of the rotating chain 202 facing away from the support member 1, and another of the receiving grooves 212 is arranged on one side of the rotating chain 202 close to the support member 1. That is, the two receiving grooves 212 are arranged opposite to each other.

As illustrated in FIG. 4 and FIG. 5, in the embodiment, the rotating chain 202 includes a first rotating chain 2021 and a second rotating chain 2022. The first rotating chain 2021 is arranged between the fixing chain 201 and the second rotating chain 2022. In the embodiment, only one first rotating chain 2021 is arranged between the fixing chain 201 and the second rotating chain 2022. In other embodiments, a plurality of first rotating chains 2021 are arranged between the fixing chain 201 and the second rotating chain 2022. Those skilled in the art can understand that the first rotating chain 2021 may not be provided between the fixing chain 201 and the second rotating chain 2022. The number of the first rotating chains 2021 depends on the angle at which the flexible display screen support mechanism 20 or the flexible display device 100 can be bent. The larger a bending angle of the flexible display screen support mechanism 20 or the flexible display device 100 is, the more the first rotating chains 2021 requires.

In the embodiment, two sliding grooves 211 are defined in the first rotating chain 2021. Three sliding grooves 211 are defined in the second rotating chain 2022. In addition, positions of the two sliding grooves 211 defined in the first rotating chain 2021 and positions of the three sliding grooves 211 defined in the second rotating chain 2022 are misaligned. Such that it can be further ensured that the supporting member 1 and the flexible display screen 10 can fit well when the flexible display device 100 changes between different states.

Please refer to FIG. 2 to FIG. 3 again, the flexible display device 100 further includes two housings 40 coupled to the hinge 2. Each of the two housings 40 is located on one side of the hinge 2. Specifically, each of the two housings 40 is coupled to the corresponding second rotating chain 2022. The support member 1 is fixedly arranged on the housing 40. In one embodiment, the support member 1 can be fixed to the housing 40 by adhesive.

Each of the two housings 40 includes a main body 41 and two mounting blocks 42 fixedly arranged on the main body 41. In one embodiment, the main body 41 and the two mounting blocks 42 are fixedly coupled by screws. Specifically, the main body 41 defines a plurality of locking holes 411, and the two mounting blocks 42 define a plurality of locking holes 420 corresponding to the plurality of locking holes 411 of the main body 41 for the screws passing through. In other embodiments, the main body 41 and the two mounting blocks 42 can also be fixedly coupled by other connection methods, such as a sliding guide structure.

The two mounting blocks 42 are arranged on two ends of one side of the main body 41 close to the second rotating chain 2022. One side of the second rotating chain 2022 close to the housing 40 protrudes two protrusions 221 connected to the housing 40. The main body 41 and each of the two mounting blocks 42 cooperatively define a position limiting sliding groove 43 for limiting a movement range of each of the two protrusions 221. Specifically, each of the two protrusions 221 is substantially T-shaped. Each of the two protrusions includes a connecting block 2211 and a sliding block 2212 arranged on one end of the connecting block 2211 close to the housing 40. A middle portion of the sliding block 2212 protrudes a positioning block 2213 smoothly coupled to the connecting block 2211.

A middle portion of each of the two mounting blocks 42 defines an opening 421 for the connecting block 2211 of each of the two protrusions 221 of the second rotating chain 2022 passing through. A side surface of each of the two mounting blocks 42 close to the main body 41 defines a sliding groove 422 in air communication with the opening 421. The positioning block 2213 is matched with the opening 421 to facilitate the sliding block 2212 to be installed in the sliding groove 422. In the embodiment, the sliding groove 422 does not penetrate the mounting block 42, and the sliding groove 422 protrudes two opposite position limiting blocks 423 from an edge of one side of the opening 421 close to the second rotating chain 2022, thus limiting the sliding block 2212 to be slidably received in the sliding groove 422. Such that the sliding connection between the housing 40 and the second rotating chain 2022 can be realized. In this embodiment, the opening 421 and the sliding groove 422 cooperatively define the position limiting sliding groove 43.

Furthermore, a side of each of two housings 40 close to the second rotating chain 2022 has a plurality of convex bars 412 arranged at intervals. A recess 413 is formed between every two adjacent bars 412. A side of the second rotating chain 2022 close to the support member 1 forms flanges 222 engaged with the recesses 413 of the housing 40, and every two adjacent flanges 422 form a recess 223 engaged with the bar 412 of the housing 40.

Please refer to FIG. 3 and FIG. 4 again, the shape and size of the position limiting fixing member 30 are similar to those of the mounting member 50. The difference is that the position limiting fixing member 30 further includes a sliding gasket 34. The sliding gasket 34 is arranged at a free end 312 of a main body 31 by a locking member 32.

Specifically, the position limiting fixing member 30 includes a cylindrical main body 31. The main body 31 includes a connecting end 311 and a free end 312 opposite to the connecting end 311. The connecting end 311 of the main body 31 is fixed on the support member 1. The free end 312 of the main body 31 is slidably coupled to the rotating chain 202. In one embodiment, the position limiting fixing member 30 further includes a locking member 32. The locking member 32 is arranged at the free end 312 of the main body 31 and abuts against the sliding groove 211.

Specifically, the free end 312 of the main body 31 defines a locking hole 3121 matched with the locking member 32 along an axial direction of the main body 31. In the embodiment, the main body 31 is a threaded sleeve, and the locking member 32 is a screw in threaded engagement with the threaded sleeve. In other embodiments, the main body 31 is operable as a stud, and the locking member 32 is operable as a nut in threaded engagement with the stud.

The position limiting fixing member 30 further includes a welding gasket 33. The main body 31 is fixed to the support member 1 by the welding gasket 33. Specifically, the main body 31 is welded to the welding gasket 33, and then the welding gasket 33 is fixed to the support member 1. The welding gasket 33 can be fixed to the support member 1 by welding. It will be apprehended that, in other embodiments, the welding gasket 33 may also be fixed to the support member 1 by gluing.

The sliding gasket 34 is arranged on one side of the sliding groove 211 facing away from the support member 1 and abuts a portion of the rotating chain 202 at an edge of the sliding groove 211. A middle portion of the sliding gasket 34 defines an opening 341 for the locking member 32 passing through, and the sliding gasket 34 is coupled to the locking member 32. The sliding gasket 34 is arranged between the main body 31 and the locking member 32, and sandwiched between the sliding groove 211 and the locking member 32. Furthermore, the welding gasket 33 is slidably received in the receiving groove 212 at one side of the rotating chain 202 close to the support member 1, and the sliding gasket 34 is slidably received in the receiving groove 212 at one side of the rotating chain 202 facing away from the support member 1, thus ensuring that the support member 1 has a flat surface after being fixedly coupled to the hinge 2.

Specifically, as illustrated in FIG. 7, the locking member 32 includes a connecting portion 321 and a position limiting portion 322. The connecting portion 321 of the locking member 32 passes through the through hole 341 of the sliding gasket 34 and is locked in the locking hole 3121 of the main body 31. A diameter of the position limiting portion 322 of the locking member 32 is larger than a diameter of the through hole 341 of the sliding gasket 34, thus achieving the locking between the locking member 32 and the sliding gasket 34, and thereby the support member 1 being slidably connected to the rotating chain 202 of the hinge 2.

As illustrated in FIG. 1 to FIG. 9, the assembly process of the position limiting fixing member 30 is as follows. In the embodiment, the connecting end 311 of the main body 31 can be pre-welded to the welding gasket 33, and then the welding gasket 33 is welded to support member 1. It will be apprehended that, in other embodiments, the welding gasket 33 can be pre-welded to the support member 1, and then the connecting end 311 of the main body 31 is welded to the welding gasket 33. The free end 312 of the main body 31 is inserted into the sliding groove 211 of the corresponding rotating chain 202. The connecting portion 321 of the locking member 32 passing through the through hole 341 of the sliding gasket 34 is inserted into one side of the rotating chain 202 facing away from the support member 1, and then is locked in the locking hole 3121 of the main body 31. At this time, the position limiting portion 322 of the locking member 32 abuts against the sliding gasket 34. That is, the sliding gasket 34 is sandwiched between the position limiting portion 322 of the locking member 32 and the main body 31. The welding gasket 33 of the limiting fixing member 30 is slidably received in the receiving groove 212 at the side of the rotating chain 202 close to the support member 1, and the sliding gasket 34 is slidably received in the receiving groove 212 at the side of the rotating chain 202 facing away from the support member 1. Such that the support member 1 still has a flat surface after the support member 1 is fixedly coupled to the hinge 2 by the position limiting fixing member 30, the flexible display screen 10 of the flexible display device 100 in the bent and unfolded state can still have a flat and continuous surface, and a problem of an irregular surface of the flexible display screen 10 being easily damaged by collision can be avoided.

During assembling the mounting member 50, the connecting end 511 of the main body 51 is welded to the welding gasket 53, and then the welding gasket 53 is welded to the support member 1. It will be apprehended that, in other embodiments, the welding gasket 53 may be pre-welded to the support member 1, and then the connecting end 511 of the main body 51 is welded to the welding gasket 53. The free end 512 of the main body 51 is inserted into the receiving groove 2012 of the corresponding fixing chain 201, and the free end 512 of the main body 51 is correspondingly received in the positioning groove 2013. The connecting portion 521 of the locking member 52 passes through the through hole 2011 at the side of the fixing chain 201 facing away from the support member 1, and is locked in the locking hole 5121 of the main body 51. It will be apprehended that, the assembling of the limit fixing member 30 and the mounting member 50 can be operated simultaneously.

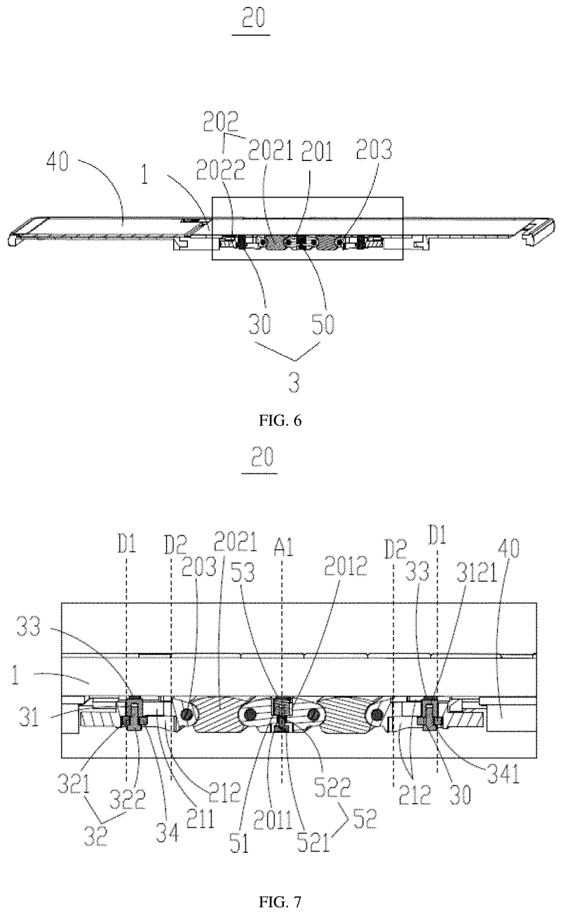

As illustrated in FIG. 6 and FIG. 7, which are schematic structural views of the flexible display screen support mechanism 20 provided by an embodiment of the present disclosure in an unfolded state. When the flexible display screen support mechanism 20 is in the unfolded state, the position limiting fixing member 30 is located at the first position D1 of the sliding groove 211 of the rotating chain 202. That is, the position limiting fixing member 30 is located at one side of the sliding groove 211 of the rotating chain 202 close to the housing 40. At this time, the support member 1 has flat upper and lower surfaces.

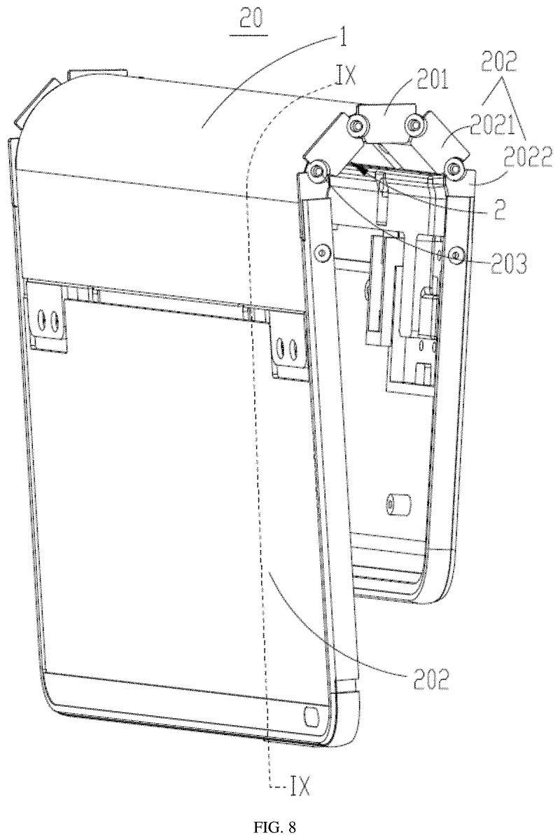

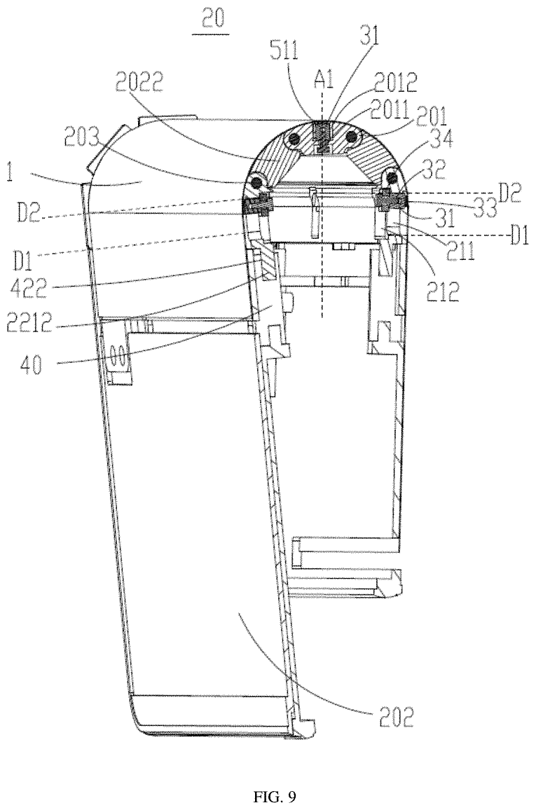

As illustrated in FIG. 8 and FIG. 9, which are schematic structural views of the flexible display screen support mechanism 20 provided by an embodiment of the present disclosure in a bending state. When the flexible display screen support mechanism 20 is in the bending state, the position limiting fixing member 30 is located at the second position D2 of the sliding groove 211 of the rotating chain 202. That is, the position limiting fixing member 30 is located at the side of the sliding groove 211 of the rotating chain 202 away from the housing 40. At this time, the support member 1 is bent into a continuous and smooth curved surface, such that the bendable area 101 of the flexible display screen 10 and the hinge 2 will not be separated, and damages caused to the flexible display screen 10 can also be avoided.

The flexible display screen support mechanism and the flexible display device of the embodiments of the present disclosure provide the position limiting apparatus passing through the hinge and fixed on the support member, thereby ensuring the connection between the support member and the hinge when the flexible display device being in different states, preventing detachment of the bendable area of the flexible display screen from the hinge, and thereby avoiding damages caused to the flexible display screen. In addition, when the two opposite ends of the flexible display screen support mechanism are squeezed, the hinge can be driven to deform by the pulling of the position limiting fixing member, such that the hinge and the support member can be arched together. Since the hinge is arched together with the support member, the support member is arched alone can be avoided, the problem of damage to the flexible display screen can be prevented or reduced.

The embodiments of the present application have been described in detail above, and the specific principles of the present application and the implementation manners have been described in specific examples. The above embodiments are only used to help understand the method of the present application and its core ideas. At the same time, persons of ordinary skill in the art, based on the idea of the present invention, will have changes in specific implementation manners and application ranges. In summary, the contents of the present specification should not be construed as limiting the present application.

What is claimed is:

1. A flexible display screen support mechanism being operable to support a flexible display screen which comprises a bendable area, comprising:
a support member arranged on a back side of the flexible display screen;
a hinge corresponding to the bendable area of the flexible display screen and arranged on one side of the support member away from the flexible display screen; and
a position limiting apparatus passing through the hinge and fixed on the support member, wherein the position limiting apparatus is operable to generate an action force to pull the support member and the hinge toward each other.

2. The flexible display screen support mechanism of claim 1, wherein the position limiting apparatus slidably passes through the hinge to be fixed on the support member.

3. The flexible display screen support mechanism of claim 1, wherein the support member comprises a support surface for supporting the flexible display screen, the position limiting apparatus passes through the hinge along a direction perpendicular to the support surface of the support member, and the position limiting apparatus is slidable along a direction parallel to the support surface of the support member.

4. The flexible display screen support mechanism of claim 1, wherein when flexible display screen support mechanism is bent, the position limiting apparatus slides relative to the hinge toward a bending central axis of the flexible display screen support mechanism.

5. The flexible display screen support mechanism of claim 1, wherein when two opposite sides of the hinge are stressed, the position limiting apparatus pulls the hinge to deform to allow the hinge and the support member to be arched together.

6. The flexible display screen support mechanism of claim 1, wherein the position limiting apparatus comprises a position limiting fixing member, the hinge comprises a rotating chain, the rotating chain defines a sliding groove for the position limiting fixing member to slide, and when the flexible display screen is bent, the position limiting fixing member slides from a first position of the sliding groove to a second position of the sliding groove.

7. The flexible display screen support mechanism of claim 6, wherein the sliding groove extends along a width direction of the rotating chain.

8. The flexible display screen support mechanism of claim 6, wherein the hinge comprises a plurality of the rotating chains, and lengths of the sliding grooves defined on different rotating chains gradually increase from the bending central axis toward a direction away from the bending central axis.

9. The flexible display screen support mechanism of claim 6, wherein the sliding groove is a through groove.

10. The flexible display screen support mechanism of claim 6, wherein the position limiting fixing member comprises a main body, the main body comprises a connecting end and a free end opposite to the connecting end, the connecting end of the main body is fixedly coupled to the support member, and the free end of the main body is slidably received in the sliding groove.

11. The flexible display screen support mechanism of claim 10, wherein the position limiting fixing member further comprises a welding gasket, and the connecting end of the main body is fixedly coupled to the support member by the welding gasket.

12. The flexible display screen support mechanism of claim 10, wherein the position limiting fixing member further comprises a locking member arranged at the free end of the main body, and the locking member abuts against the sliding groove.

13. The flexible display screen support mechanism of claim 10, wherein the main body is a threaded sleeve, and the locking member is a screw in threaded engagement with the threaded sleeve.

14. The flexible display screen support mechanism of claim 12, wherein the position limiting fixing member further comprises a sliding gasket arranged between the main body and the locking member, and the sliding gasket is arranged on one side of the sliding groove facing away from the support member, and abuts on a portion of the rotating chain at an edge of the sliding groove.

15. The flexible display screen support mechanism of claim 6, wherein the hinge comprises a plurality of the rotating chains, the hinge further comprises a fixing chain arranged between the plurality of the rotating chains, the fixing chain is fixedly arranged on the support member, and at least one of the plurality of rotating chains and the fixing chain are hinged to each other.

16. The flexible display screen support mechanism of claim 15, wherein when the hinge is bent, the plurality of the rotating chains rotate relative to each other around the fixing chain.

17. The flexible display screen support mechanism of claim 15, wherein the position limiting apparatus further comprises a mounting member, and the fixing chain is fixedly arranged on the support member by the mounting member.

18. The flexible display screen support mechanism of claim 15, wherein the fixing chain defines a through hole for the mounting member passing through.

19. The flexible display screen support mechanism of claim 1, wherein the support member is made of liquid metal material.

20. A flexible display device, comprising a flexible display screen support mechanism and a flexible display screen, wherein the flexible display screen support mechanism is arranged on a back side of the flexible display screen, the flexible display screen support mechanism is operable to support the flexible display screen which comprises a bendable area, and the flexible display screen support mechanism comprises:
a support member arranged on a back side of the flexible display screen;
a hinge corresponding to the bendable area of the flexible display screen and arranged on one side of the support member away from the flexible display screen; and
a position limiting apparatus passing through the hinge and fixed on the support member, wherein the position limiting apparatus is operable to generate an action force to pull the support member and the hinge toward each other.
